(19) United States
(12) Patent Application Publication
(10) Pub. No.: US 2019/0260301 A1
(43) Pub. Date: Aug. 22, 2019

(54) SWITCHING POWER SUPPLY DEVICE

(71) Applicant: Panasonic Intellectual Property Management Co., Ltd., Osaka (JP)

(72) Inventors: JUNICHI YUKAWA, Kanagawa (JP); HISAZUMI WATANABE, Osaka (JP)

(21) Appl. No.: 16/086,029

(22) PCT Filed: Oct. 27, 2016
(86) PCT No.: PCT/JP2016/004725

§ 371 Date: Sep. 18, 2018

(30) Foreign Application Priority Data
Mar. 25, 2016 (JP) 2016-061098

(51) Int. Cl. H02M 7/00; H02M 7/5387; H01L 23/64; H01L 23/473; H01L 25/16

(52) U.S. Cl. CPC H02M 7/003; H02M 7/5387; H02P 27/06; H01L 23/473; H01L 25/16; H01L 23/642

(57) ABSTRACT

A conductive layer is provided on one surface to an insulating layer, and has a power-source-side trace, a ground-side trace, and an output-side trace. A first switching element is surface-mounted on the power-source-side trace and connected to the output-side trace. A second switching element is surface-mounted on the output-side trace and connected to the ground-side trace. A capacitor is surface-mounted on the ground-side trace and connected to the power-source-side trace or the output-side trace.

### TECHNICAL FIELD

The present disclosure relates to a switching power supply device.

### BACKGROUND ART

Heretofore, switching power supply devices are known. Switching power supply devices are disclosed in PTL 1 or the like, for example. PTL 1 discloses a motor controller including a plurality of field-effect transistor (FET) chips that controls an electric current to be supplied to a motor from a power source, a plurality of diode chips that is connected to drains of the respective FET chips with anode connection, and a smoothing capacitor that is connected to the power source in parallel. In the motor controller, the FET chips and the diode chips are fixed to a printed wiring board, and the smoothing capacitor is disposed above the printed wiring board with a terminal bar. Specifically, the terminal bar is a member for connecting the smoothing capacitor to the power source, and includes a fixing portion to be fixed to a printed wiring board, an upright portion extending upward from the fixing portion, and a power source connection portion extending forward from an upper end or an intermediate portion of the upright portion. The smoothing capacitor includes a connection terminal attached to the upright portion of the terminal bar.

### CITATION LIST

### Patent Literature

PTL 1: Unexamined Japanese Patent Publication No. 2002-262593

### SUMMARY OF THE INVENTION

A switching power supply device of the present disclosure includes an insulating layer, a conductive layer, a first switching element, a second switching element, and a capacitor. The conductive layer is provided on one surface to the insulating layer, and has a power-source-side trace, a ground-side trace, and an output-side trace. The first switching element is surface-mounted on the power-source-side trace and connected to the output-side trace. The second switching element is surface-mounted on the output-side trace and connected to the ground-side trace. The capacitor is surface-mounted on the ground-side trace and electrically connected to the power-source-side trace or the output-side trace.

According to the present disclosure, thermal environment of a capacitor can be improved while surge voltage caused by switching operation is reduced.

### BRIEF DESCRIPTION OF DRAWINGS

FIG. 1 is a circuit diagram illustrating a configuration example of a switching power supply device according to an exemplary embodiment.

FIG. 2 is a schematic plan view illustrating a configuration example of the switching power supply device according to the exemplary embodiment.

FIG. 3 is a schematic sectional view illustrating a configuration example of the switching power supply device according to the exemplary embodiment.

FIG. 4 is a schematic plan view illustrating a modification of a switching power supply device according to the exemplary embodiment.

### DESCRIPTION OF EMBODIMENTS

Prior to description of exemplary embodiments of the present disclosure, problems of conventional devices will be briefly described.

In the motor controller of PTL 1, the smoothing capacitor is disposed above the printed wiring board, so that the connection terminal of the smoothing capacitor is attached to the upright portion (an upright portion extending upward from the fixing portion) of the terminal bar instead of the fixing portion (a fixing portion to be fixed to the printed wiring board) of the terminal bar. This increases a wiring route from the smoothing capacitor to the FET chip provided in the printed wiring board as compared to a case where the smoothing capacitor is attached to the printed wiring board. As a result, it is difficult to reduce parasitic inductance in the wiring route from the smoothing capacitor to the FET chip to make it difficult to reduce surge voltage caused by switching operation of the FET chip.

While it is conceivable that a smoothing capacitor is attached to a printed wiring board, the smoothing capacitor comes closer to a FET chip provided in the printed wiring board as compared to a case where the smoothing capacitor is disposed above the printed wiring board. This causes heat generated in the FET chip to be likely to be transmitted to the smoothing capacitor. As a result, it is difficult to reduce a temperature rise of the smoothing capacitor, caused by heat generated in the FET chip, to make it difficult to improve thermal environment of the smoothing capacitor.

Hereinafter, exemplary embodiments will be described in detail with reference to drawings. The same or equivalent portion in the drawings is designated by same reference numeral to eliminate duplicated description.

### (Switching Power Supply Device)

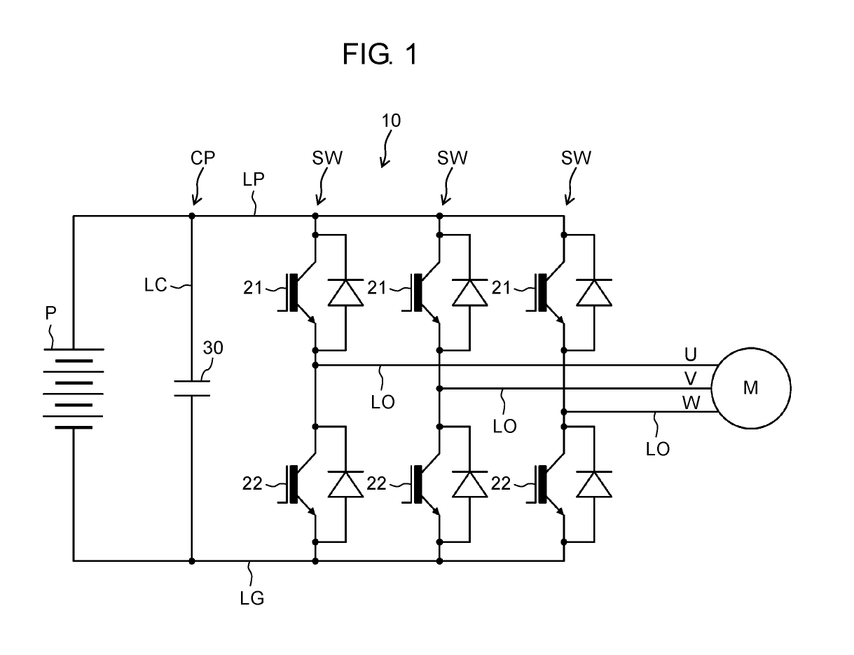

FIG. 1 illustrates a configuration example of switching power supply device 10 according to an exemplary embodiment. Switching power supply device 10 is configured to convert electric power supplied from a power source (DC power supply P in this example) to output electric power using switching operation to supply the output electric power to a driving object (motor M in this example). In this example, switching power supply device 10 constitutes an inverter for converting DC power to three-phase AC power.

Switching power supply device 10 includes power supply line LP, ground line LG, one or more output lines LO, one or more switching parts SW, and capacitor section CP. In this example, power supply line LP is connected to one end (cathode) of DC power supply P, and ground line LG is connected to the other end (anode) of DC power supply P. Switching power supply device 10 includes three output lines LO and three switching parts SW. The three switching parts are respectively connected to the three phases (U, V, W) of motor M via three output lines LO.

Switching part SW is connected between power supply line LP and ground line LG. Switching part SW has an intermediate node that is connected to motor M via output line LO. Switching part SW has first switching element 21 and second switching element 22. First switching element 21 (or second switching element 22) in FIG. 1 is connected to a freewheel diode in parallel, the freewheel diode corresponding to a parasitic diode parasitic in first switching element 21 (or second switching element 22).

Capacitor section CP is connected between power supply line LP and ground line LG. Capacitor section CP has capacitor 30. Capacitor section CP is provided with connection line LC that connects capacitor 30 to power supply line LP.

### [Structure of Switching Power Supply Device]

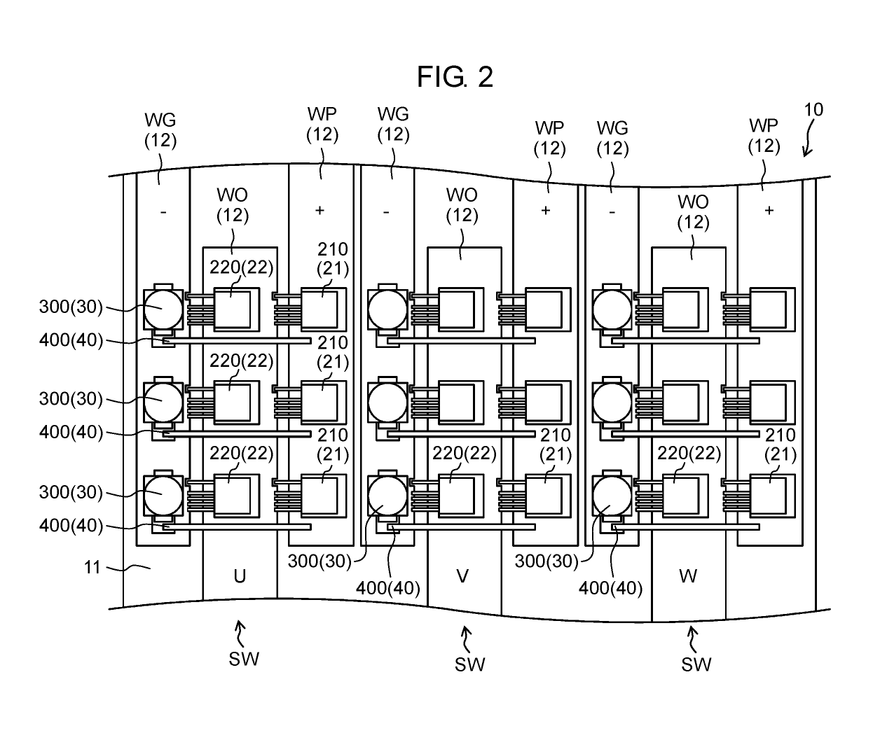

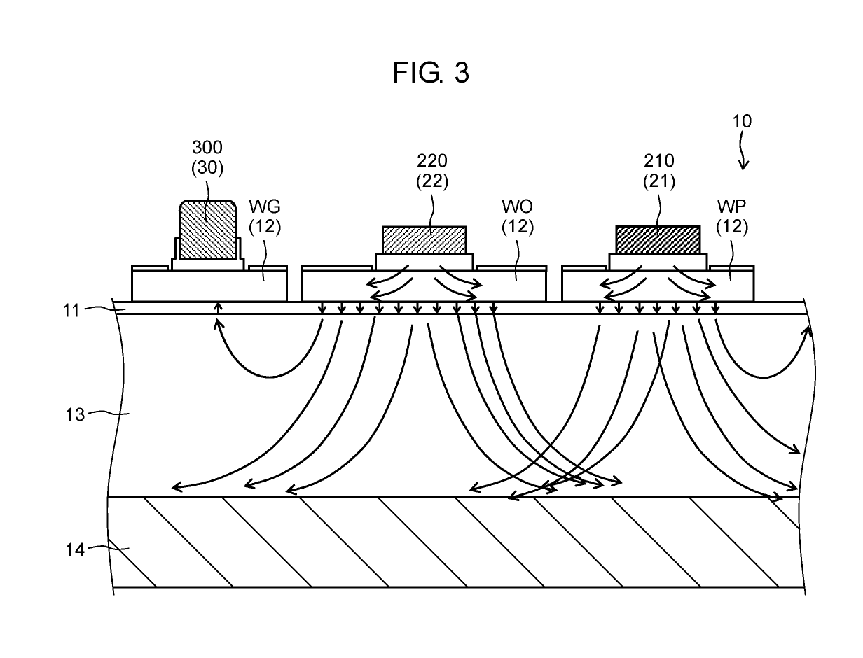

Next, structure of switching power supply device 10 will be described with reference to FIGS. 2 and 3. FIG. 2 is a schematic plan view of switching power supply device 10, and FIG. 3 is a schematic sectional view of switching power supply device 10. In FIG. 3, hatching of a part of the section is eliminated to simplify the illustration. Switching power supply device 10 includes insulating layer 11, conductive layer 12, and heat dissipation layer 13.

### <Insulating Layer>

Insulating layer 11 is formed of insulating material (e.g., an epoxy resin sheet, etc.), and formed in a plate shape.

### <Conductive Layer>

Conductive layer 12 is formed of conductive material (e.g., copper, etc.), and is provided on one surface of insulating layer 11 while being formed in a foil shape. Conductive layer 12 is provided with a trace pattern. The trace pattern includes one or more power-source-side traces WP, one or more ground-side traces WG, and one or more output-side traces WO. In conductive layer 12, power-source-side trace WP, ground-side trace WG, and output-side trace WO are separated from each other to prevent a short-circuit.

### <Heat Dissipation Layer>

Heat dissipation layer 13 is formed of heat-transfer material (e.g., aluminum, etc.), and is provided on the other surface of insulating layer 11. Heat dissipation layer 13 is connected to cooling member 14. Cooling member 14 is provided to cool heat dissipation layer 13. Cooling member 14 is configured to be cooled by water cooling (cooling with cooling water) or oil cooling (cooling with cooling oil), for example.

In this example, insulating layer 11 has a thickness smaller than a thickness of each of conductive layer 12 and heat dissipation layer 13. Heat dissipation layer 13 has a thickness greater than the thickness of conductive layer 12. For example, insulating layer 11 may have a thickness set to about 100 μm, conductive layer 12 may have a thickness set to about 200 μm, and heat dissipation layer 13 may have a thickness set to about 1 mm to 3 mm. Then, insulating layer 11 has a coefficient of thermal conductivity lower than a coefficient of thermal conductivity of each of conductive layer 12 and heat dissipation layer 13. Conductive layer 12 has a coefficient of thermal conductivity higher than a coefficient of thermal conductivity of heat dissipation layer 13.

In this example, conductive layer 12 has three power-source-side traces WP, three ground-side traces WG, and three output-side traces WO. One of power-source-side traces WP, one of ground-side traces WG, and one of output-side traces WO constitute one trace set, and three trace sets are disposed in a first direction (a lateral direction in FIG. 2). As illustrated in FIG. 1, switching power supply device 10 includes three first switching element 21 and three second switching element 22, and one of first switching elements 21 and one of second switching elements 22 constitute one switching part SW. Three switching parts SW correspond to respective three trace sets, as illustrated in FIG. 2. In the example of FIG. 2, three switching elements (hereinafter referred to as first independence switching elements 210) are connected in parallel to constitute one first switching element 21 (one of first switching elements 21 in FIG. 1), and three switching elements (hereinafter referred to as second independence switching elements 220) are connected in parallel to constitute one second switching element 22 (one of second switching elements 22 in FIG. 1). Thus, in the example of FIG. 2, nine first independence switching elements 210 and nine second independence switching elements 220 exist. Hereinafter, each part of switching power supply device 10 will be described with a focus on one trace set and one switching part SW.

### <Power-Source-Side Trace, Ground-Side Trace, and Output-Side Trace>

Power-source-side trace WP constitutes a part of power supply line LP illustrated in FIG. 1, ground-side trace WG constitutes a part of ground line LG illustrated in FIG. 1, and output-side trace WO constitutes a part of output line LO illustrated in FIG. 1.

Power-source-side trace WP, ground-side trace WG, and output-side trace WO are disposed so as to be parallel to each other. Output-side trace WO is disposed between power-source-side trace WP and ground-side trace WG. In this example, each of power-source-side trace WP, ground-side trace WG, and output-side trace WO is formed in a plate shape extending in a second direction (a vertical direction in FIG. 2) orthogonal to the first direction.

### <First Switching Element>

First switching element 21 is surface-mounted on power-source-side trace WP and connected to output-side trace WO. Specifically, first switching element 21 is mounted on power-source-side trace WP, and has one end (drain/heat dissipation surface) joined to a front surface of power-source-side trace WP with solder, and the other end (source) is connected to output-side trace WO with a wiring member such as a bonding wire. First switching element 21 has a gate that is connected to a first gate trace (not illustrated) with the wiring member. No large current flows through the first gate trace. This enables the first gate trace to be formed in an elongated shape in a trace pattern.

In this example, first switching element 21 includes three first independence switching elements 210, as described above. Three first independence switching elements 210 are arrayed in a longitudinal direction of power-source-side trace WP, and are each surface-mounted on the power-source-side trace WP to be connected to the output-side trace WO. First independence switching elements 210 each have a gate that is connected to the first gate trace (not illustrated) with the wiring member. First independence switching elements 210 each may include a field effect transistor (FET) of a surface-mounted type, for example.

### <Second Switching Element>

Second switching element 22 is surface-mounted on output-side trace WO and connected to ground-side trace WG. Specifically, second switching element 22 is mounted on output-side trace WO, and has one end (drain/heat dissipation surface) joined to a front surface of output-side trace WO with solder, and the other end (source) is connected to ground-side trace WG with a wiring member such as a bonding wire. Second switching element 22 has a gate that is connected to a second gate trace (not illustrated) with the wiring member. No large current flows through the second gate trace. This enables the second gate trace to be formed in an elongated shape in a trace pattern.

In this example, second switching element 22 includes three second independence switching elements 220, as described above. Three second independence switching elements 220 are arrayed in the longitudinal direction of output-side trace WO, and are each surface-mounted on output-side trace WO and connected to ground-side trace WG. Second independence switching elements 220 each have a gate that is connected to the second gate trace (not illustrated) with the wiring member. Second independence switching elements 220 each may include a field effect transistor (FET) of a surface-mounted type, for example.

### <Capacitor and Connection Parts>

Switching power supply device 10 includes capacitor 30 and connection parts 40. Capacitor 30 is mounted on ground-side trace WG and electrically connected to power-source-side trace WP. Connection parts 40 constitute connection line LC illustrated in FIG. 1 to electrically connect capacitor 30 to power-source-side trace WP. Specifically, capacitor 30 is mounted on ground-side trace WG, and has one end (anode) joined to ground-side trace WG with solder, and the other end (cathode) is electrically connected to power-source-side trace WP with connection parts 40.

In this example, capacitor 30 includes nine independence capacitors 300. Connection parts 40 include nine independence connection parts 400. Then, three independence capacitors 300 and three independence connection parts 400 are disposed on each of three ground-side traces WG. The configuration described above allows all nine independence capacitors 300 to be electrically connected in parallel.

Three independence capacitors 300 disposed on one ground-side trace WG are arrayed in the longitudinal direction of ground-side trace WG, and are surface-mounted on ground-side trace WG and electrically connected to power-source-side trace WP (for details, power-source-side trace WP belonging to the same trace set as ground-side trace WG). In this example, independence capacitors 300 are disposed inside an outer edge of ground-side trace WG in plan view. That is, independence capacitors 300 do not extend out from ground-side trace WG in plan view in this example. Independence capacitors 300 each may include an electrolytic capacitor of a surface-mounted type, for example, or may include a film capacitor of a surface-mounted type.

Three independence connection parts 400 disposed on one ground-side trace WG electrically connect the respective three independence capacitors disposed on ground-side trace WG to power-source-side trace WP (for details, power-source-side trace WP belonging to the same trace set as ground-side trace WG). In this example, independence connection parts 400 each are formed in an elongated plate shape extending in the first direction (the lateral direction in FIG. 2). Independence connection parts 400 each may include a bus bar, a jumper, or another wiring member, for example.

In this example, first independence switching elements 210, second independence switching elements 220, and independence capacitors 300 are disposed so as to align in the first direction (the lateral direction in FIG. 2).

### [Heat Transfer]

Next, heat transfer in switching power supply device 10 will be described with reference to FIG. 3.

As indicated by arrows in FIG. 3, when first switching element 21 generates heat with switching operation of first switching element 21, heat is transferred from first switching element 21 to power-source-side trace WP (conductive layer 12). The heat transferred to power-source-side trace WP is transferred through power-source-side trace WP toward insulating layer 11 while spreading in a direction orthogonal to a lamination direction. The heat transferred to insulating layer 11 is transferred through insulating layer 11 toward mainly heat dissipation layer 13. The heat transferred to heat dissipation layer 13 is transferred through heat dissipation layer 13 toward mainly cooling member 14.

As indicated by arrows in FIG. 3, when second switching element 22 generates heat with switching operation of second switching element 22, heat is transferred from second switching element 22 to output-side trace WO (conductive layer 12). The heat transferred to output-side trace WO is transferred through output-side trace WO toward insulating layer 11 while spreading in the direction orthogonal to the lamination direction. The heat transferred to insulating layer 11 is transferred through insulating layer 11 toward mainly heat dissipation layer 13. The heat transferred to heat dissipation layer 13 is transferred through heat dissipation layer 13 toward mainly cooling member 14.

Power-source-side trace WP and ground-side trace WG are separated in conductive layer 12, so that heat transfer from power-source-side trace WP to ground-side trace WG is blocked. Likewise, output-side trace WO and ground-side trace WG are separated in conductive layer 12, so that heat transfer from output-side trace WO to ground-side trace WG is blocked. As described above, heat is less likely to be transferred from power-source-side trace WP and output-side trace WO toward ground-side trace WG.

Insulating layer 11 has a thickness smaller than a thickness of each of conductive layer 12 and heat dissipation layer 13, and insulating layer 11 has a coefficient of thermal conductivity lower than a coefficient of thermal conductivity of each of conductive layer 12 and heat dissipation layer 13. Thus, heat is less likely to spread in the direction orthogonal to the lamination direction in insulating layer 11. Heat transfer from power-source-side trace WP and output-side trace WO toward ground-side trace WG via insulating layer 11 is therefore blocked, so that heat is less likely to be transferred from power-source-side trace WP and output-side trace WO toward ground-side trace WG via insulating layer 11.

### Effect of Exemplary Embodiment

In switching power supply device 10, first switching element 21 is surface-mounted on power-source-side trace WP, second switching element 22 is surface-mounted on output-side trace WO, and capacitor 30 is surface-mounted on ground-side trace WG. That is, first switching element 21, second switching element 22, and capacitor 30 are each surface-mounted on conductive layer 12. Thus, capacitor 30 can be disposed near first switching element 21 and second switching element 22. As a result, a length of a wiring route from capacitor 30 to first switching element 21 can be shortened, and a length of a wiring route from capacitor 30 to second switching element 22 can be shortened. Thus, parasitic inductance in the wiring routes can be reduced, so that surge voltage caused by switching operation of each of first and second switching elements 21, 22 can be reduced.

In switching power supply device 10, ground-side trace WG is separated from power-source-side trace WP and output-side trace WO, so that heat is less likely to be transferred from power-source-side trace WP and output-side trace WO toward ground-side trace WG. This enables a temperature rise of capacitor 30, caused by heat generation of first and second switching elements 21, 22, to be reduced even when first and second switching elements 21, 22 generate heat with switching operation of first and second switching elements 21, 22. As a result, thermal environment of capacitor 30 can be improved.

When capacitor 30 includes a plurality of independence capacitors 300 arrayed in the longitudinal direction of ground-side trace WG, heat of capacitor 30 can be dispersed. This enables a temperature rise of capacitor 30, caused by heat generation of first and second switching elements 21, 22, to be reduced, so that thermal environment of capacitor 30 can be improved.

When connection parts 40 for electrically connecting capacitor 30 to power-source-side trace WP include a plurality of independence connection parts 400, heat is less likely to be transferred from power-source-side trace WP toward capacitor 30 via connection parts 40 as compared to a case where connection parts 40 include one thick wiring member. This enables a temperature rise of capacitor 30, caused by heat generation of first switching element 21 to be reduced, so that thermal environment of capacitor 30 can be improved.

When first switching element 21 includes a plurality of first independence switching elements 210 arrayed in the longitudinal direction of power-source-side trace WP, heat generated in first switching element 21 (heat caused by switching operation of first switching element 21) can be dispersed. This enables an amount of heat to be transferred from first switching element 21 toward power-source-side trace WP to be reduced, so that a temperature rise of capacitor 30, caused by heat generation of first switching element 21, can be reduced. As a result, thermal environment of capacitor 30 can be improved.

When second switching element 22 includes a plurality of second independence switching elements 220 arrayed in the longitudinal direction of output-side trace WO, heat generated in second switching element 22 (heat caused by switching operation of second switching element 22) can be dispersed. This enables an amount of heat to be transferred from second switching element 22 toward output-side trace WO to be reduced, so that a temperature rise of capacitor 30, caused by heat generation of second switching element 22, can be reduced. As a result, thermal environment of capacitor 30 can be improved.

When power-source-side trace WP, ground-side trace WG, and output-side trace WO, are disposed so as to be parallel to each other, first switching element 21 surface-mounted on power-source-side trace WP, capacitor 30 surface-mounted on ground-side trace WG, and second switching element 22 surface-mounted on output-side trace WO, can be disposed close to each other. This enables not only parasitic inductance in a wiring route from capacitor 30 to first switching element 21 but also parasitic inductance in a wiring route from capacitor 30 to second switching element 22 to be reduced. As a result, surge voltage caused by switching operation of each of first and second switching elements 21, 22 can be reduced.

When output-side trace WO is disposed between power-source-side trace WP and ground-side trace WG, not only connection between first switching element 21 surface-mounted on power-source-side trace WP and output-side trace WO, but also connection between second switching element 22 surface-mounted on output-side trace WO and ground-side trace WG, can be facilitated.

When heat dissipation layer 13 is provided on the other surface of insulating layer 11, heat can be transferred from insulating layer 11 to heat dissipation layer 13. This enables heat transfer from power-source-side trace WP and output-side trace WO toward ground-side trace WG via insulating layer 11 to be blocked, so that a temperature rise of capacitor 30, caused by heat generation of first and second switching elements 21, 22, can be reduced. As a result, thermal environment of capacitor 30 can be improved.

When cooling member 14 is attached to heat dissipation layer 13, heat transfer from power-source-side trace WP and output-side trace WO toward heat dissipation layer 13 via insulating layer 11 can be promoted. This enables heat transfer from power-source-side trace WP and output-side trace WO toward ground-side trace WG via insulating layer 11 to be blocked, so that a temperature rise of capacitor 30, caused by heat generation of first and second switching elements 21, 22, can be reduced. As a result, thermal environment of capacitor 30 can be improved.

### (Modification of Switching Power Supply Device)

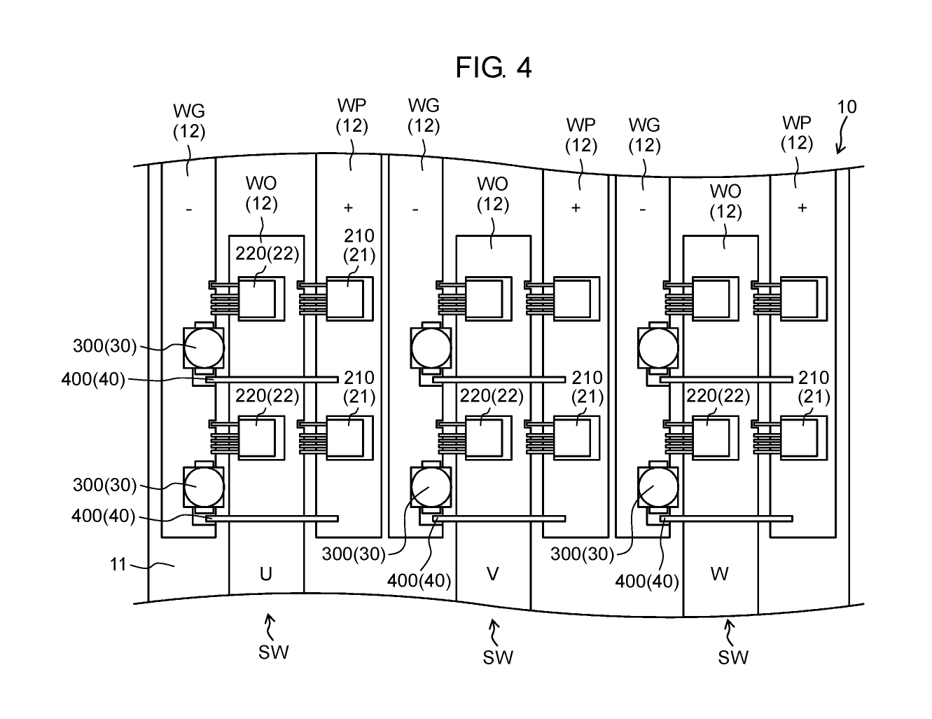

As illustrated in FIG. 4, a number of first independence switching elements 210 constituting first switching element 21 is not limited to three, and may be two, or four or more. The same applies to second independence switching elements 220, independence capacitors 300, and independence connection parts 400. The number of first independence switching elements 210 constituting first switching element 21 may be identical to a number of second independence switching elements 220 constituting second switching element 22, or may be different from the number of second independence switching elements 220. A number of independence connection parts 400 may be identical to a number of independence capacitors 300, or may be more than the number of independence capacitors 300.

As illustrated in FIG. 4, first independence switching elements 210, second independence switching elements 220, and independence capacitors 300 may not be disposed so as to align in the first direction (the lateral direction in FIG. 2).

As illustrated in FIG. 4, a part of independence capacitors 300 may be disposed outside the outer edge of ground-side trace WG in plan view. That is, independence capacitors 300 may extend out from ground-side trace WG in plan view.

### Other Exemplary Embodiments

While the description above shows first switching element 21 that includes a plurality of first independence switching elements 210, for example, first switching element 21 may include one first independence switching element 210. For example, first switching element 21 may include one field effect transistor of a surface-mounted type.

While second switching element 22 including a plurality of second independence switching elements 220 is described, for example, second switching element 22 may include one second independence switching element 220. For example, second switching element 22 may include one field effect transistor of a surface-mounted type.

While capacitor 30 including a plurality of independence capacitors 300 is described, for example, capacitor 30 may include one independence capacitor 300. For example, capacitor 30 may include one electrolytic capacitor of a surface-mounted type (or one film capacitor of a surface-mounted type, etc.).

While connection parts 40 including a plurality of independence connection parts 400 are described, for example, connection parts 40 may include one independence connection part 400. For example, connection parts 40 may include one bus bar (or one jumper, or one wiring member, etc.).

While the description above shows capacitor 30 that is electrically connected to power-source-side trace WP with connection parts 40, for example, capacitor 30 may be electrically connected to output-side trace WO with connection parts 40. A specific example will be described later in detail.

Switching power supply device 10 may constitute an inverter for converting DC power (or AC power) into AC power with switching operation, or may constitute a converter for converting DC power (or AC power) into DC power with switching operation. For example, switching power supply device 10 may constitute a DC-DC converter (a converter for converting input DC power into output DC power with a voltage value different from that of input DC power with switching operation). The DC-DC converter includes a step-down converter, a step-up converter, and a bidirectional DC-DC converter.

When switching power supply device 10 constitutes a step-down converter, capacitor 30 has one end connected to ground-side trace WG, and has the other end electrically connected to output-side trace WO with an inductor.

When switching power supply device 10 constitutes a step-up converter, capacitor 30 has one end connected to ground-side trace WG, and has the other end connected to power-source-side trace WP. In consideration of a direction in which an electric current flows in a step-up converter, output-side trace WO serves as a power source side trace, and power-source-side trace WP serves as an output side trace. However, it is defined herein that trace WO is referred to as “output-side trace WO” even when serving as a power source side trace, and trace WP is referred to as “power-source-side trace WP” even when serving as an output side trace.

When switching power supply device 10 constitutes a bidirectional DC-DC converter, switching power supply device 10 is provided with two capacitors 30. One of capacitors 30 has one end connected to ground-side trace WG, and has the other end connected to output-side trace WO. The other of capacitors 30 has one end connected to ground-side trace WG, and has the other end connected to power-source-side trace WP.

As described above, capacitor 30 is surface-mounted on ground-side trace WG and electrically connected to power-source-side trace WP or output-side trace WO in switching power supply device 10. When capacitor 30 includes a plurality of independence capacitors 300, connection parts 40 for electrically connecting capacitor 30 to power-source-side trace WP or output-side trace WO may include a plurality of independence connection parts 400 for electrically connecting the corresponding plurality of independence capacitors 300 to power-source-side trace WP or output-side trace WO.

The exemplary embodiments and the modifications described above may be appropriately combined to be practiced. The exemplary embodiments and the modifications described above each are merely intrinsically preferable exemplary, and are not intended to limit the disclosure, its application, or its use.

### INDUSTRIAL APPLICABILITY

As described above, the present disclosure is applicable to a switching power supply device.

### REFERENCE MARKS IN THE DRAWINGS

10 switching power supply device

11 insulating layer

12 conductive layer

13 heat dissipation layer

14 cooling member

21 first switching element

210 first independence switching element

22 second switching element

220 second independence switching element

30 capacitor

300 independence capacitor

40 connection parts

400 independence connection parts

WP power-source-side trace

WG ground-side trace

WO output-side trace

SW switching part

CP capacitor section

1. A switching power supply device comprising:
an insulating layer;
a conductive layer provided on one side of the insulating layer and including a power-source-side trace, a ground-side trace, and an output-side trace;
a first switching element surface-mounted on the power-source-side trace and connected to the output-side trace;
a second switching element surface-mounted on the output-side trace and connected to the ground-side trace; and
a plurality of capacitors surface-mounted on the ground-side trace and electrically connected to the power-source-side trace or the output-side trace,
wherein the plurality of the capacitors are mounted on the ground-side trace, and are arrayed lengthwise along the ground-side trace,
the plurality of the capacitors are surface-mounted on the ground-side trace so as to allow an anode of each of the capacitors to be joined to the ground-side trace, and
the plurality of the capacitors each have a cathode that is electrically connected to the power-source-side trace or the output-side trace with independence connection parts in an elongated plate shape.

2. The switching power supply device according to claim 1, wherein
the plurality of capacitors are a plurality of independence capacitors that are arrayed lengthwise along the ground-side trace, and that are electrically connected to each other in parallel.

3. The switching power supply device according to claim 2, further comprising connection parts for electrically connecting the plurality of capacitors to the power-source-side trace or the output-side trace,
the connection parts including a plurality of independence connection parts that each electrically connect to a corresponding one of the plurality of independence capacitors to the power-source-side trace or the output-side trace.

4. The switching power supply device according to claim 1, wherein
the first switching element includes a plurality of first independence switching elements that are arrayed lengthwise along the power-source-side trace, and that are electrically connected to each other in parallel.

5. The switching power supply device according to claim 1, wherein
the second switching element includes a plurality of second independence switching elements that are arrayed lengthwise along the output-side trace, and that are electrically connected to each other in parallel.

6. The switching power supply device according to claim 1, wherein
the power-source-side trace, the ground-side trace, and the output-side trace are disposed so as to be parallel to each other.

7. The switching power supply device according to claim 6, wherein
the output-side trace is disposed between the power-source-side trace and the ground-side trace.

8. The switching power supply device according to claim 1, further comprising a heat dissipation layer provided on an other side of the insulating layer.

9. The switching power supply device according to claim 8, wherein
the heat dissipation layer is attached to a cooling member for cooling the heat dissipation layer.
